(19) United States
(12) Patent Application Publication
(10) Pub. No.: US 2025/0140649 A1
(43) Pub. Date: May 1, 2025

(54) INTEGRATED CIRCUIT DEVICES WITH BACKSIDE SEMICONDUCTOR STRUCTURES

(71) Applicant: Intel corporation, Santa Clara, CA (US)

(72) Inventors: Feng Zhang, Hillsboro, OR (US); Tao Chu, Portland, OR (US); Minwoo Jang, Portland, OR (US); Yanbin Luo, Portland, OR (US); Guowei Xu, Portland, OR (US); Ting-Hsiang Hung, Beaverton, OR (US); Chiao-Ti Huang, Portland, OR (US); Robin Chao, Portland, OR (US); Chia-Ching Lin, Portland, OR (US); Yang Zhang, Rio Rancho, NM (US); Kan Zhang, HILLSBORO, OR (US)

(73) Assignee: Intel Corporation, Santa Clara, CA (US)

(21) Appl. No.: 18/498,340

(22) Filed: Oct. 31, 2023

(51) Int. Cl. H01L 23/48; H01L 27/092; H01L 29/06; H01L 29/778; H01L 29/786

(52) U.S. Cl. CPC H01L 23/481; H10D 30/47; H10D 30/6757; H10D 62/118; H10D 84/85

(57) ABSTRACT

An IC device may include a semiconductor structure and a backside semiconductor structure over the semiconductor structure. The semiconductor structure and backside semiconductor structure may constitute the source or drain region of a transistor. The backside semiconductor structure may be closer to the backside of a substrate of the IC device than the semiconductor structure. The backside semiconductor structure may be formed at a lower temperature than the semiconductor structure. The backside semiconductor structure may have one or more different materials from the semiconductor structure. For instance, a semiconductor material in the backside semiconductor structure may have a different crystal direction from a semiconductor material in the semiconductor structure. As another example, the backside semiconductor structure may have one or more different chemical compounds from the semiconductor structure. The backside semiconductor structure may be over a backside via that can couple the backside semiconductor structure to a backside metal layer.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on. Metal layers can be arranged at both the frontside and the backside of the semiconductor devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device with backside semiconductor structures, according to some embodiments of the disclosure.

FIG. 2 illustrates an IC device with a backside semiconductor structure, according to some embodiments of the disclosure.

FIGS. 3A-3F illustrate a process of forming an IC device with backside semiconductor structures, according to some embodiments of the disclosure.

FIGS. 4A-4H illustrate a process of forming an IC device with a backside semiconductor structure, according to some embodiments of the disclosure.

FIGS. 5A-5F illustrate a process of forming backside semiconductor structures in a CMOS (complementary metal-oxide-semiconductor) IC device, according to some embodiments of the disclosure.

FIGS. 6A and 6B are top views of a wafer and dies that may include one or more IC devices with backside semiconductor structures, according to some embodiments of the disclosure.

FIG. 7 is a side, cross-sectional view of an example IC package that may include one or more IC devices with backside semiconductor structures, according to some embodiments of the disclosure.

FIG. 8 is a cross-sectional side view of an IC device assembly that may include components having one or more IC devices with backside semiconductor structures, according to some embodiments of the disclosure.

FIG. 9 is a block diagram of an example computing device that may include one or more components including one or more IC devices with backside semiconductor structures, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

The FEOL stage of forming IC devices typically requires epitaxial growth, e.g., for forming epitaxial semiconductor structures (also referred to as “epitaxial structures”) to be used as source regions and drain regions of transistors. However, currently available technologies for epitaxial growth are facing challenges in avoiding defects in the epitaxial structures. For instance, the bottom epitaxial structures usually have voids as epitaxial fill is missed due to limited access to the precursor blocked by the top epitaxial structures. The top epitaxial structures can also have defects as large epitaxial structures can cause shorts between the epitaxial structures. In some cases, epitaxial structures may be etched out during etch processes required to form other components in the IC devices. Also, there can be erosion of epaxial structures due to certain removal processes, e.g., sub-fin removal processes. The defects in epitaxial structures can significantly impair the performance of IC devices. For instance, such defects can cause a reduction in the amount of electrical current that the transistors can provide. Therefore, improved technologies for epitaxial growth are needed.

Embodiments of the present disclosure may improve on at least some of the challenges and issues described above by providing IC devices with backside semiconductor structures. A backside semiconductor structure may be formed through a backside epitaxial growth process. For instance, the backside semiconductor structure may be formed over a pre-formed semiconductor structure to remove one or more defects in the pre-formed semiconductor structure. The backside semiconductor structure in the present disclosure can solve the missing epitaxial fill or epitaxial structure erosion problems and therefore, improve performances of IC devices.

In various embodiment of the present disclosure, an IC device may include a transistor. The source or drain region of the transistor may include a semiconductor structure and a backside semiconductor structure. The backside semiconductor structure may be closer to the backside of the IC device (e.g., closer to the backside of the transistor or to the backside of a support structure) than the semiconductor structure to the backside of the IC device. The semiconductor structure may be formed at a higher temperature than the backside semiconductor structure. The difference in the temperature for forming the semiconductor structure and the backside semiconductor structure may be at least 100° C. The backside semiconductor structure may have one or more different materials from the semiconductor structure. For instance, a semiconductor material in the backside semiconductor structure may have a different crystal direction from a semiconductor material in the semiconductor structure. As another example, the backside semiconductor structure may have one or more different chemical compounds from the semiconductor structure.

The semiconductor structure may be formed over a substrate. To form the backside semiconductor structure, a portion of the substrate may be removed. In some embodiments, a portion of the semiconductor structure may also be removed. The surface formed from the removal process may be treated to make it ready for epitaxial growth. The backside semiconductor structure may be formed over the surface. In some embodiments, a conductive structure (e.g., a via) may be formed over the backside semiconductor structure. The conductive structure may couple the backside semiconductor structure to a backside metal layer.

Backside semiconductor structures can be formed in both N-type transistors and P-type transistors. For an IC device that includes both a N-type transistor and a P-type transistor (e.g., an IC device fabricated through a CMOS process), backside semiconductor structures can be formed in the N-type transistor and P-type transistor separately. For instance, the N-type transistor may be covered with a mask when one or more backside semiconductor structures are formed in the P-type transistor. Also, the P-type transistor may be covered with a mask when one or more backside semiconductor structures are formed in the N-type transistor.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

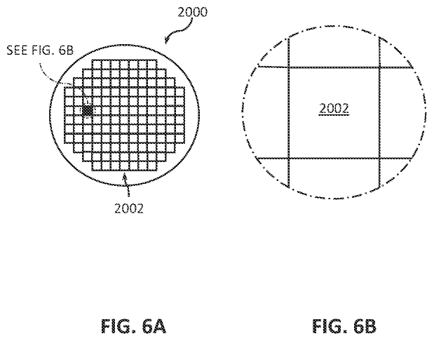

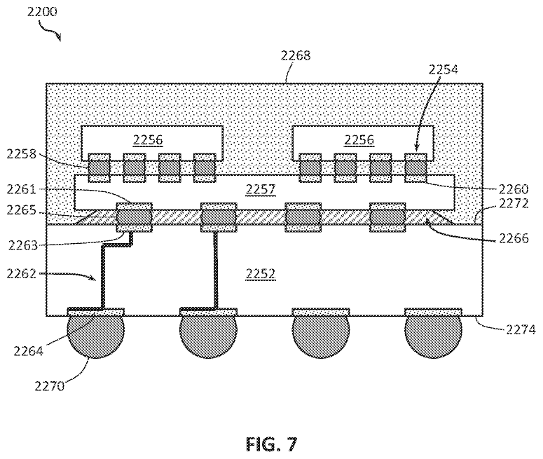

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 6A and 6B, such a collection may be referred to herein without the letters, e.g., as “FIG. 6.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of backside semiconductor structures as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various backside semiconductor structures as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

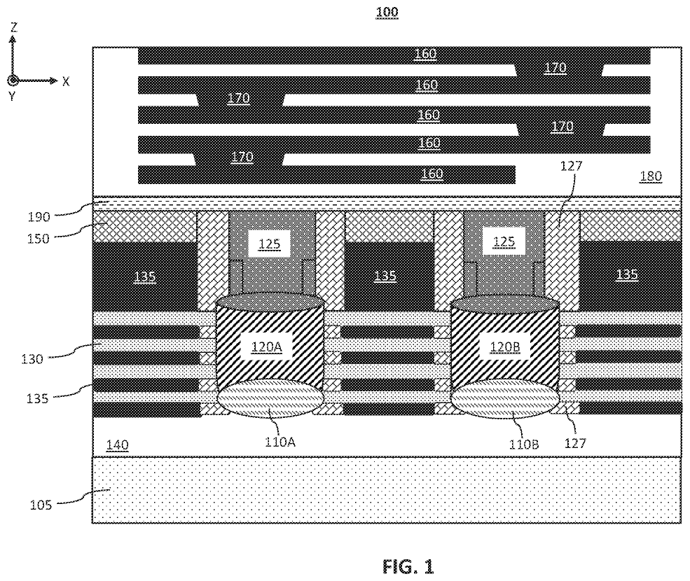

FIG. 1 illustrates an IC device 100 with backside semiconductor structures 110A and 110B (collectively referred to as “backside semiconductor structures 110” or “backside semiconductor structure 110”), according to some embodiments of the disclosure. The IC device 100 also includes a support structure 105, semiconductor structures 120A and 120B (collectively referred to as “semiconductor structures 120” or “semiconductor structure 120”), electrodes 125 (individually referred to as “electrode 125”), spacers 127 (individually referred to as “spacer 127”), semiconductor structures 130 (individually referred to as “semiconductor structure 130”), electrodes 135 (individually referred to as “electrode 135”), an electrical insulator 140, a gate insulating layer 150, metal layers 160, vias 170, another electrical insulator 180, and a contact layer 190. In other embodiments, the IC device 100 may include fewer, more, or different components. For example, the IC device 100 may include one or more semiconductor devices not shown in FIG. 1. As another example, the IC device 200 may include a different number of backside semiconductor structures, semiconductor structures, electrodes, metal layers, vias, etc.

The support structure 105 may be any suitable structure, such as a substrate, a die, a wafer, or a chip. The support structure 105 may, e.g., be the wafer 2000 of FIG. 6A, discussed below, and may be, or be included in, a die, e.g., the singulated die 2002 of FIG. 6B, discussed below. Semiconductor devices, e.g., transistors, may be built over the support structure 105. In some embodiments, the support structure 105 may be a semiconductor substrate composed of semiconductor material systems including, for example, N-type or P-type materials systems, and, in some embodiments, the channel region, described herein, may be a part of the support structure 105. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure 105 may be a printed circuit board (PCB) substrate. One or more transistors, such as the transistor may be built on the support structure 105.

Although a few examples of materials from which the support structure 105 may be formed are described here, any material that may serve as a foundation upon which an IC may be built falls within the spirit and scope of the present disclosure. In various embodiments, the support structure 105 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 105 may provide material “support” in that, e.g., the IC devices/structures described herein are build based on the semiconductor materials of the support structure 105. However, in some embodiments, the support structure 105 may provide mechanical support.

The backside semiconductor structures 110 are closer to the support structure 105 and the electrical insulator 140 than the semiconductor structures 120. In some embodiments, the backside semiconductor structures 110 may be formed after the semiconductor structures 120 are formed. The backside semiconductor structures 110 may be formed at a lower temperature than the semiconductor structures 120. For instance, the temperature for forming the backside semiconductor structures 110 may be at least 100° C. lower than the temperature for forming the semiconductor structures 120.

In some embodiments, the backside semiconductor structures 110 and the semiconductor structures 120 have crystal structures. A backside semiconductor structure 110 or a semiconductor structure 120 may be formed through an epitaxial growth process, in which a crystal material may be formed with one or more well-defined orientations with respect to a crystal substrate after the material is deposited onto the crystal substrate. The backside semiconductor structures 110 and the semiconductor structures 120 may also be referred to as epitaxial structures or epitaxial semiconductor structures. The crystal substrate used for epitaxial growth may be a die or wafer. The crystal direction of the epitaxial structures may be determined based on a crystal direction in the crystal substrate.

The backside semiconductor structures 110 may have one or more different semiconductor materials from the semiconductor structures 120. For instance, the backside semiconductor structures 110 may be formed with depositing a different semiconductor material or using a different precursor for the deposition from the semiconductor structures 120. The backside semiconductor structures 110 may have one or more different chemical compounds from the semiconductor structures 120. Additionally or alternative, the backside semiconductor structures 110 may have different crystal directions (or crystallographic directions) from the semiconductor structures 120. The crystal direction of a crystal structure may be an orientation orthogonal to a lattice plane of the crystal structure. A lattice plane may be a plane whose intersections with the lattice are periodic, e.g., a plane of a surface of a unit crystal cell. The crystal direction of a crystal structure may be represented by Miller indices, such as [100], [010], [001], [110], [111], and so on.

The semiconductor structures 130 may be semiconductor structures having non-planar shapes. In the embodiments of FIG. 1, the semiconductor structures 130 are nanoribbons. A semiconductor structure 130 may have a longitudinal axis along the X axis. The semiconductor structure 130 may also have a transverse cross-section that is perpendicular to the longitudinal axis. The transverse cross-section may be in the Y-Z plane. The dimension of the semiconductor structure 120 along the X axis may be greater (e.g., significantly greater) than the dimension of the semiconductor structure 120 along the Y axis or along the Z axis. In other embodiments, the semiconductor structures 130 may be fins. In yet other embodiments, the semiconductor structures 130 may be planar structurers.

The backside semiconductor structures 110, semiconductor structures 120, and the semiconductor structures regions 130 may be semiconductor regions in transistors. In an example, the backside semiconductor structure 110A and the semiconductor structure 120A may constitute a source region of a transistor. The backside semiconductor structure 110B and the semiconductor structure 120B may constitute a drain region of the transistor. In another example, the backside semiconductor structure 110A and the semiconductor structure 120A may be the drain region, while the backside semiconductor structure 110B and the semiconductor structure 120B may be the source region. Portions of the semiconductor structures 130 between the source region and drain region may constitute the channel region of the transistor. Examples of the transistors include field-effect transistor (FET), such as metal-oxide-semiconductor FET (MOSFET), tunnel FET (TFET), fin-based transistor (e.g., FinFET), nanoribbon-based transistor, gate-all-around (GAA) transistor, other types of FET, or some combination thereof. In some embodiments, the IC device 100 may be formed through a CMOS fabrication process. The IC device 100 may include one or more N-type transistors (e.g., N-type metal-oxide-semiconductor (NMOS) transistors) and one or more P-type transistors (e.g., P-type metal-oxide-semiconductor (PMOS) transistors).

A channel region of a transistor may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where the transistor is an NMOS transistor or an N-type TFET), the channel material may advantageously include a III-V material having a high electron mobility, such as, but not limited to InGaAs, InP, InSb, and InAs. For some such embodiments, the channel material may be a ternary III—V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a Ill-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the transistor is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region and the drain region are connected to the channel region. The source region and the drain region each include a semiconductor material with dopants. In some embodiments, the source region and the drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

The two electrodes 125 are over the two semiconductor structures 120, respectively. Each electrode 125 may be a source electrode or a drain electrode of a transistor. A source electrode is an electrode over a source region. A drain electrode is an electrode over a drain region. The electrode 125 may be coupled to a power source for delivering power to the source or drain region. In some embodiments, the electrodes 125 may be at different electrical potentials during the operation of the IC device. One of the electrodes 125 may be coupled to a power plane, and the other one of the electrodes 125 may be coupled to a ground plane. Each electrode 125 includes one or more electrically conductive materials, such as metals. Examples of metals in the electrode 145A and the electrode 145B may include, but are not limited to, ruthenium (Ru), copper (Cu), cobalt (Co), palladium (Pd), platinum (Pt), nickel (Ni), and so on.

The electrodes 135 may be gate electrodes of transistors. An electrode 135 may be over a channel region of a transistor. A transistor also includes a gate that is over or wraps around at least a portion of the channel region. The gate includes a gate electrode and a gate insulator. The gate electrode can be coupled to a gate terminal that controls gate voltages applied on the transistor. The gate electrode may include one or more gate electrode materials, where the choice of the gate electrode materials may depend on whether the transistor is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrodemay include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate insulator separates at least a portion of the channel region from the gate electrode so that the channel region is insulated from the gate electrode. In some embodiments, the gate insulator may wrap around at least a portion of the channel region. The gate insulator may also wrap around at least a portion of the source region or the drain region. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The spacers 127 may be electrically insulative. The spacer 127 may separate components in the IC device 100 from each other so that these components are not undesirably coupled to each other. For instance, some spacers 127 may separate some or all of the electrodes 135 from the backside semiconductor structures 110 and the semiconductor structures 120. Some spacers 127 separate some or all of the electrodes 135 from some or all of the electrodes 125. The electrical insulator 140 is between the backside semiconductor structures 110 and the support structure 105. The electrical insulator 140 also separates some of the electrodes 135 from the support structure 105. Also, the gate insulating layer 150 may insulate some or all of the electrodes 135 from other components in the IC device 100, e.g., the electrodes 125, the contact layer 190, and so on. In some embodiments, a spacer 127, the electrical insulator 140, and the gate insulating layer 150 includes one or more insulating materials, such as the electrical insulators described above.

The metal layers 160 are stacked over the support structure 105 and transistors (e.g., transistors including the backside semiconductor structures 110, semiconductor structures 120, and semiconductor structures 130) along the Z axis. In some embodiments, the metal layers 160 are frontside metal layers that are arranged at the frontside of the support structure 105. The IC device 100 may also include one or more backside metal layers (not shown in FIG. 1) at the backside of the support structure 105. A metal year 160 may include one or more metal lines, which is also referred to as interconnects. A metal line may have a longitudinal axis, which may be along the X axis or Y axis. In some embodiments, the metal lines in the same metal layer 160 may be in parallel. The metal lines in two adjacent metal layers may be perpendicular to each other. The metal layers 160 may be coupled with other devices than the transistor, such as diodes, power sources, resistors, capacitors, inductors, sensors, transceivers, receivers, antennas, and so on. The metal layers 160 may be used to deliver power or signal to such devices.

As shown in FIG. 1, the metal layers 160 may be coupled to each other using the vias 170. A via 170 may be connected to two or more metal layers 160 and have a longitudinal axis perpendicular to the metal layers 160. The electrical connections between the metal layers 160 may be different from the electrical connections shown in FIG. 1. Also, even though not shown in FIG. 1, the IC device 100 may include other vias that couple one or more metal layers 160 to one or more of the electrodes 125 and 135. A metal layer 160 may provide power or signal to an electrode 125 or 135. The electrical insulator 180 surrounds the metal layers 160 and vias 170. The electrical insulator 180 may include one or more electrically insulating materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc. In some embodiments, the metal layers 160, vias 170 and electrical insulator 180 may constitute a BEOL section of the IC device 100 and may be fabricated in a BEOL process. The metal layer 160 that is closest to the support structure 105 may be referred to as M0, the next metal layer 160 may be referred to as M1, and so on.

The contact layer 190 may facilitate bonding or coupling of the BEOL section of the IC device 100 with the rest of the IC device 100. The contact layer 190 may include a bonding material, e.g., glue. In some embodiments, the contact layer 190 may include one or more electrically conductive structures for coupling one or more metal layers 160 to other components of the IC device, such as one or more electrodes 125 and 135.

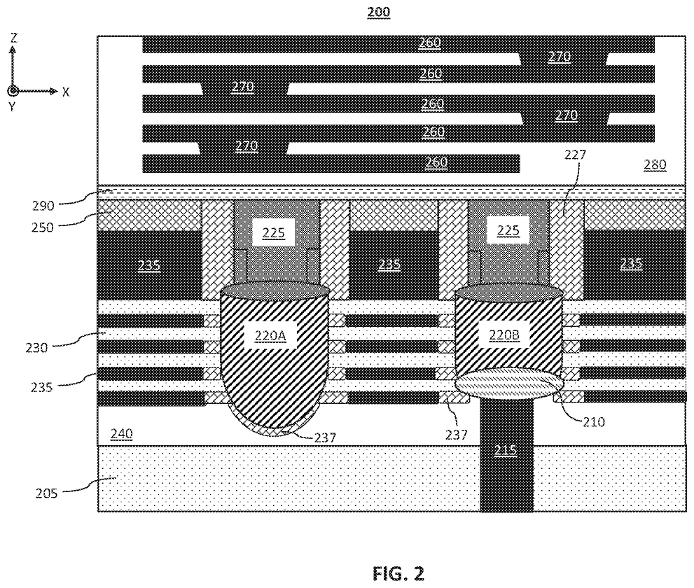

FIG. 2 illustrates an IC device with a backside semiconductor structure 210, according to some embodiments of the disclosure. The IC device 200 also includes a support structure 205, a backside via 215, semiconductor structures 220A and 220B (collectively referred to as “semiconductor structures 220” or “semiconductor structure 220”), electrodes 225 (individually referred to as “electrode 225”), spacers 227 (individually referred to as “spacer 227”), semiconductor structures 230 (individually referred to as “semiconductor structure 230”), electrodes 235 (individually referred to as “electrode 235”), an electrical insulator 240, a gate insulating layer 250, metal layers 260, vias 270, another electrical insulator 280, and a contact layer 290. In other embodiments, the IC device 200 may include fewer, more, or different components. For example, the IC device 200 may include one or more semiconductor devices not shown in FIG. 2. As another example, the IC device 200 may include a different number of backside semiconductor structures, semiconductor structures, electrodes, metal layers, vias, etc.

The support structure 205 may be any suitable structure, such as a substrate, a die, a wafer, or a chip. The support structure 205 may, e.g., be the wafer 2000 of FIG. 6A, discussed below, and may be, or be included in, a die, e.g., the singulated die 2002 of FIG. 6B, discussed below. Semiconductor devices, e.g., transistors, may be built over the support structure 205. In some embodiments, the support structure 205 may be a semiconductor substrate composed of semiconductor material systems including, for example, N-type or P-type materials systems, and, in some embodiments, the channel region, described herein, may be a part of the support structure 205. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure 205 may be a PCB substrate. One or more transistors, such as the transistor may be built on the support structure 205.

Although a few examples of materials from which the support structure 205 may be formed are described here, any material that may serve as a foundation upon which an IC may be built falls within the spirit and scope of the present disclosure. In various embodiments, the support structure 205 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 205 may provide material “support” in that, e.g., the IC devices/structures described herein are build based on the semiconductor materials of the support structure 205. However, in some embodiments, the support structure 205 may provide mechanical support.

The backside semiconductor structure 210 is closer to the support structure 205 and the electrical insulator 240 than the semiconductor structures 220. The backside semiconductor structure 210 is over the backside via 215. In some embodiments, an end of the backside via 215 abuts a surface of the backside semiconductor structure 210. The backside via 215 extends along the Z axis. The backside via 215 may have a longitudinal axis along the Z axis and a transverse cross-section in the X-Y plane. The dimension of the backside via 215 along the Z axis may be greater (e.g., significantly greater) than the dimension of the backside via 215 along the X axis or Y axis. As shown in FIG. 2, the backside via 215 extends from the backside semiconductor structure 210 to the support structure 205. The backside via 215 penetrates the electrical insulator 240 and the support structure 205. In other embodiments, the backside via 215 may penetrate part of the support structure 205 or part of the electrical insulator 240. The backside via 215 may be conductive and may couple the backside semiconductor structure 210 to a backside metal layer (not shown in FIG. 2) of the IC device 200. For instance, the backside metal layer may be a power plane or ground plane. The backside via 215 may facilitate backside power delivery.

In some embodiments, the backside semiconductor structure 210 may be formed after the semiconductor structures 220 are formed. The backside semiconductor structure 210 may be formed at a lower temperature than the semiconductor structures 220. For instance, the temperature for forming the backside semiconductor structure 210 may be at least 200° C. lower than the temperature for forming the semiconductor structures 220.

In some embodiments, the backside semiconductor structure 210 and the semiconductor structures 220 have crystal structures. A backside semiconductor structure 210 or a semiconductor structure 220 may be formed through an epitaxial growth process, in which a crystal material may be formed with one or more well-defined orientations with respect to a crystal substrate after the material is deposited onto the crystal substrate. The backside semiconductor structure 210 and the semiconductor structures 220 may also be referred to as epitaxial structures or epitaxial semiconductor structures. The crystal substrate used for epitaxial growth may be a die or wafer. The crystal direction of the epitaxial structures may be determined based on a crystal direction in the crystal substrate.

The backside semiconductor structure 210 may have one or more different semiconductor materials from the semiconductor structures 220. For instance, the backside semiconductor structure 210 may be formed with depositing a different semiconductor material or using a different precursor for the deposition from the semiconductor structures 220. Chemical compounds in the backside semiconductor structure 210 may be different from chemical compounds in the semiconductor structures 220. Additionally or alternative, the backside semiconductor structure 210 may have different crystal directions (or crystallographic directions) from the semiconductor structures 220. The crystal direction of a crystal structure may be an orientation orthogonal to a lattice plane of the crystal structure. A lattice plane may be a plane whose intersections with the lattice are periodic, e.g., a plane of a surface of a unit crystal cell. The crystal direction of a crystal structure may be represented by Miller indices, such as [100], [010], [001], [110], [111], and so on.

The semiconductor structures 230 may be semiconductor structures having non-planar shapes. In the embodiments of FIG. 2, the semiconductor structures 230 are nanoribbons. A semiconductor structure 230 may have a longitudinal axis along the X axis. The semiconductor structure 230 may also have a transverse cross-section that is perpendicular to the longitudinal axis. The transverse cross-section may be in the Y-Z plane. The dimension of the semiconductor structure 220 along the X axis may be greater (e.g., significantly greater) than the dimension of the semiconductor structure 220 along the Y axis or along the Z axis. In other embodiments, the semiconductor structures 230 may be fins. In yet other embodiments, the semiconductor structures 230 may be planar structurers.

The backside semiconductor structure 210, semiconductor structures 220, and the semiconductor structures 230 may be semiconductor regions in transistors. In an example, the semiconductor structure 220A may be a source region of a transistor, and the backside semiconductor structure 210 and the semiconductor structure 220B may constitute a drain region of the transistor. In another example, the semiconductor structure 220A may be the drain region, while the backside semiconductor structure 210 and the semiconductor structure 220B may be the source region. Portions of the semiconductor structures 230 between the source region and drain region may constitute the channel region of the transistor. A source region or drain region may include one or more semiconductor material with dopants, such as the ones described above. A channel region of a transistor may include a channel material, such as the channel materials described above. Examples of the transistors include FET, such as metal-oxide-semiconductor FET (MOSFET), tunnel FET (TFET), fin-based transistor (e.g., FinFET), nanoribbon-based transistor, GAA transistor, other types of FET, or some combination thereof. In some embodiments, the IC device 200 may be formed through a CMOS fabrication process. The IC device 200 may include one or more N-type transistors (e.g., NMOS) and one or more P-type transistors (e.g., PMOS).

The two electrodes 225 are over the two semiconductor structures 220, respectively. Each electrode 225 may be a source electrode or a drain electrode of a transistor. A source electrode is an electrode over a source region. A drain electrode is an electrode over a drain region. The electrode 225 may be coupled to a power source for delivering power to the source or drain region. In some embodiments, the electrodes 225 may be at different electrical potentials during the operation of the IC device. One of the electrodes 225 may be coupled to a power plane, and the other one of the electrodes 225 may be coupled to a ground plane. Each electrode 225 includes one or more electrically conductive materials, such as metals. Examples of metals in the electrode 245A and the electrode 245B may include, but are not limited to, ruthenium (Ru), copper (Cu), cobalt (Co), palladium (Pd), platinum (Pt), nickel (Ni), and so on. The electrodes 235 may be gate electrodes of transistors, such as gate electrodes described above. An electrode 235 may be over a channel region of a transistor.

The spacers 227 may be electrically insulative. The spacer 227 may separate components in the IC device 200 from each other so that these components are not undesirably coupled to each other. For instance, some spacers 227 may separate some or all of the electrodes 235 from the backside semiconductor structure 210 and the semiconductor structures 220. Some spacers 227 separate some or all of the electrodes 235 from some or all of the electrodes 225. The electrical insulator 240 is between the backside semiconductor structure 210 and the support structure 205. The electrical insulator 240 also separates some of the electrodes 235 from the support structure 205. Also, the gate insulating layer 250 may insulate some or all of the electrodes 235 from other components in the IC device 200, e.g., the electrodes 225, the contact layer 290, and so on. In some embodiments, a spacer 227, the electrical insulator 240, and the gate insulating layer 250 includes one or more insulating materials, such as the electrical insulators described above.

The metal layers 260 are stacked over the support structure 205 and transistors (e.g., transistors including the backside semiconductor structure 210, semiconductor structures 220, and semiconductor structures 230) along the Z axis. In some embodiments, the metal layers 260 are frontside metal layers that are arranged at the frontside of the support structure 205. The IC device 200 may also include one or more backside metal layers (not shown in FIG. 2) at the backside of the support structure 205. A metal year 260 may include one or more metal lines, which is also referred to as interconnects. A metal line may have a longitudinal axis, which may be along the X axis or Y axis. In some embodiments, the metal lines in the same metal layer 260 may be in parallel. The metal lines in two adjacent metal layers may be perpendicular to each other. The metal layers 260 may be coupled with other devices than the transistor, such as diodes, power sources, resistors, capacitors, inductors, sensors, transceivers, receivers, antennas, and so on. The metal layers 260 may be used to deliver power or signal to such devices.

As shown in FIG. 2, the metal layers 260 may be coupled to each other using the vias 270. A via 270 may be connected to two or more metal layers 260 and have a longitudinal axis perpendicular to the metal layers 260. The electrical connections between the metal layers 260 may be different from the electrical connections shown in FIG. 2. Also, even though not shown in FIG. 2, the IC device 200 may include other vias that couple one or more metal layers 260 to one or more of the electrodes 225 and 235. A metal layer 260 may provide power or signal to an electrode 225 or 235. The electrical insulator 280 surrounds the metal layers 260 and vias 270. The electrical insulator 280 may include one or more electrically insulating materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc. In some embodiments, the metal layers 260, vias 270 and electrical insulator 280 may constitute a BEOL section of the IC device 200 and may be fabricated in a BEOL process. The metal layer 260 that is closest to the support structure 205 may be referred to as M0, the next metal layer 260 may be referred to as M1, and so on.

The contact layer 290 may facilitate bonding or coupling of the BEOL section of the IC device 200 with the rest of the IC device 200. The contact layer 290 may include a bonding material, e.g., glue. In some embodiments, the contact layer 290 may include one or more electrically conductive structures for coupling one or more metal layers 260 to other components of the IC device, such as one or more electrodes 225 and 235.

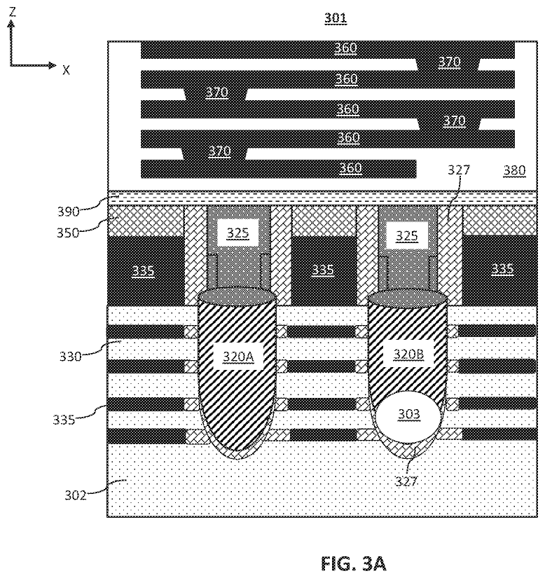

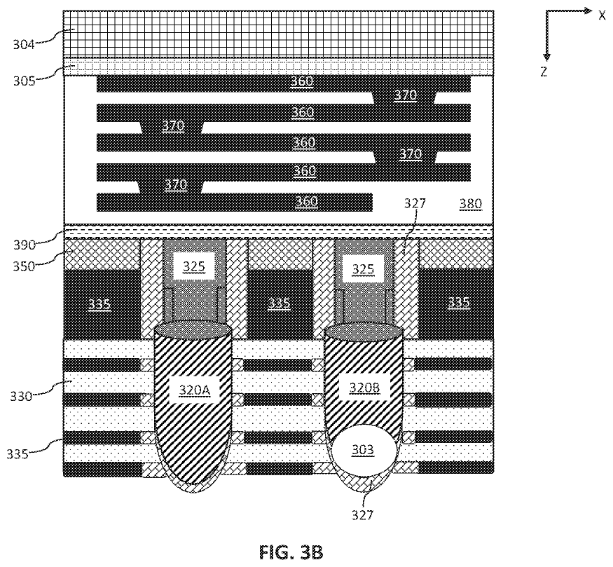

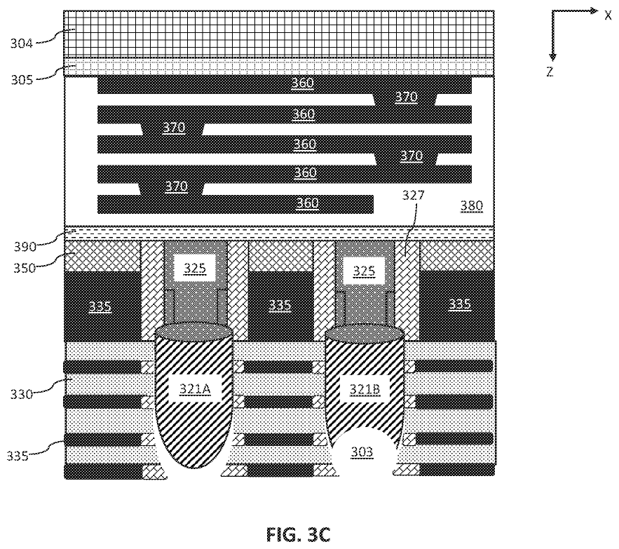

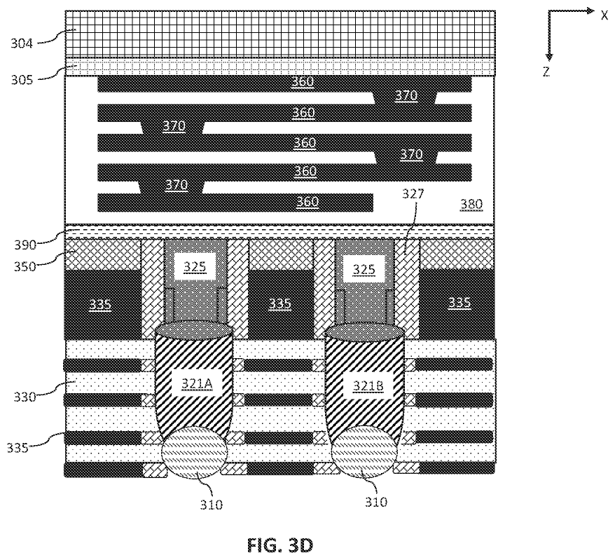

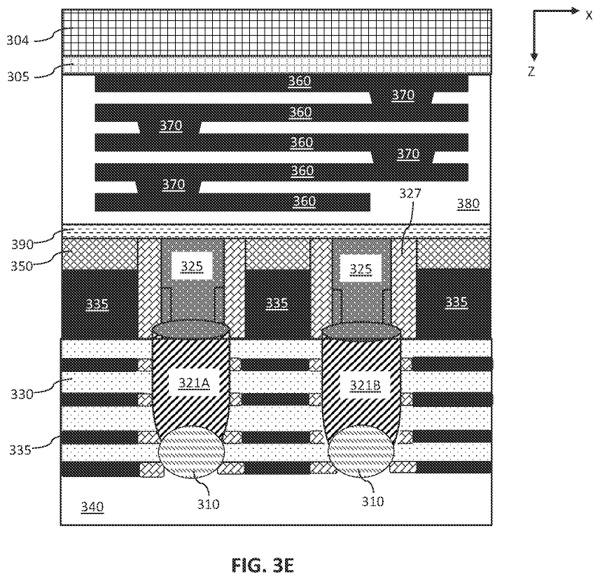

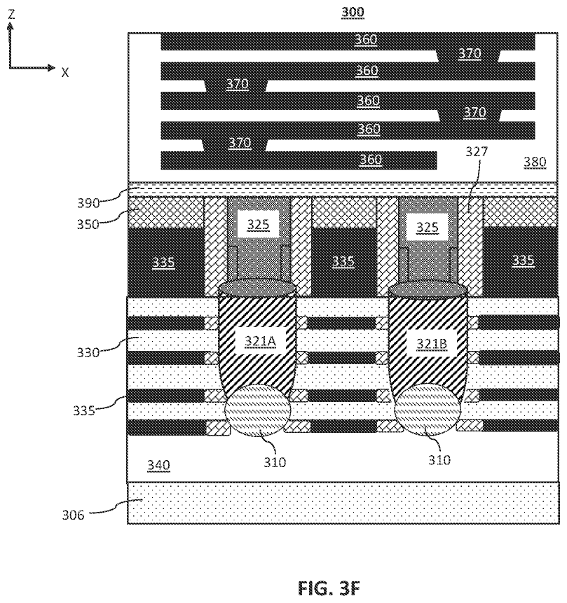

FIGS. 3A-3F illustrate a process of forming an IC device 300 with backside semiconductor structures 310, according to some embodiments of the disclosure. The IC device 300 may be an example of the IC device 100 in FIG. 1. Although the process is described with reference to the flowchart illustrated in FIGS. 3A-3F, many other processes for forming IC devices with backside semiconductor structures may alternatively be used. For example, the order of the steps described in conjunction with FIGS. 3A-3F may be changed. As another example, some of the steps may be changed, eliminated, or combined.

FIG. 3A shows a preliminary IC device 301 that includes a semiconductor region 302, semiconductor structures 320A and 320B (collectively referred to as “semiconductor structures 320” or “semiconductor structure 320”), electrodes 325 (individually referred to as “electrode 325”), spacers 327 (individually referred to as “spacer 327”), semiconductor structures 330 (individually referred to as “semiconductor structure 330”), electrodes 335 (individually referred to as “electrode 335”), a gate insulating layer 350, metal layers 360, vias 370, another electrical insulator 380, and a contact layer 390. In other embodiments, the IC device 300 may include fewer, more, or different components. The preliminary IC device 301 may have been formed before the steps illustrated in FIGS. 3B-3F are performed.

The semiconductor structures 320 may include semiconductor materials with dopants, such as the ones described above. As shown in FIG. 3A, the semiconductor structure 320B has a defect 303, which may be a void. The defect 303 can impair the performance of the preliminary IC device 301. The electrodes 325 may be examples of the electrodes 125. The semiconductor structures 330 may be examples of the semiconductor structures 130. The electrodes 335 may be examples of the electrodes 135. The gate insulating layer 350 may be an example of the gate insulating layer 150. The metal layers 360 may be examples of the metal layers 160. The vias 370 may be examples of the vias 170. The electrical insulator 380 may be an example of the electrical insulator 180. The contact layer 390 may be an example of the contact layer 190.

In FIG. 3B, the preliminary IC device 301 is flipped upside down, as illustrated by the Z axis in FIG. 3B. A carrier substrate 304 is attached to the preliminary IC device 301 using a bonding layer 305. The bonding layer may include one or more bonding materials that can affix the carrier substrate 304 onto the preliminary IC device 301. The carrier substrate 304 may facilitate the rest of the process for forming the IC device 100. In some embodiments, after the carrier substrate 304 is attached, the semiconductor region 302 is removed, e.g., through etch, polish, other processes, or some combination thereof. In some embodiments, the entire semiconductor region 302 is removed. In other embodiments, part of the semiconductor region 302 is removed.

In FIG. 3C, the spacers 327 that wraps around the bottom tips of the semiconductor structures 320 are removed, e.g., through etch or polish. Also, part of the semiconductor structure 320A is removed to form a semiconductor structure 321A. In some embodiments, the bottom edge of the semiconductor structure 321A may be aligned or almost aligned with the bottom edge of the semiconductor structure 320B. As the spacer 327 wrapping around the bottom tip of the semiconductor structure 320B is removed, the defect 303 is exposed.

In FIG. 3D, the backside semiconductor structures 310 are formed. In some embodiments, the backside semiconductor structures 310 may be formed through a low-temperature epitaxial growth process. For instance, one or more semiconductor materials may be deposited at a relatively low temperature. The backside semiconductor structures 310 are formed through epitaxial growth of the semiconductor materials. One or more precursors may be used for facilitating the epitaxial growth. In some embodiments, the temperature of the epitaxial growth may be below approximately 400° C. Such a temperature is lower compared with the temperature for forming the semiconductor structures 320. For instance, the semiconductor structures 320 may be formed at a temperature above approximately 500° C., e.g., temperatures in a range from approximately 500° C. to approximately 600° C. The lower-temperature epitaxial growth can avoid damage to the other components in the preliminary IC device 301.

The lower-temperature epitaxial growth may use different precursors from the high-temperature epitaxial growth used to grow the semiconductor structures 320. Examples of precursors for the lower-temperature epitaxial growth may include high order precursors, such as Si₂H₆ and Ge₂H₆. Examples of precursors for the lower-temperature epitaxial growth may include SiH4, GeH4, Dichlorosilane (DSC, H₂SiCl₂), hydrochloric acid (HCl), and so on. Given the usage of different precursors in the epitaxial growth processes, the backside semiconductor structures 310 may have one or more different chemical compounds from the semiconductor structures 320. In some embodiments, the backside semiconductor structures 310 may be formed after a surface treatment process that treats the surfaces on which the backside semiconductor structures 310 are to be formed. The surface treatment process may include physical treatment or chemical treatment. The surface treatment process may clean the surfaces, change one or more chemical compounds at the surfaces, or change the surface in other manners to get the surface ready for epitaxial growth.

In FIG. 3E, an electrical insulator 340 is added. The electrical insulator 340 is over the backside semiconductor structures 310. At least part of each backside semiconductor structure 310 may be surrounded by the electrical insulator 340. The electrical insulator 340 may be an example of the electrical insulator 140.

In FIG. 3F, a support structure 306 is formed over the electrical insulator 340. The support structure 306 may be an example of the support structure 105. Also, the carrier substrate 304 and the bonding layer 305 are removed. The IC device 300 is formed and flipped back, as indicated by the Z axis in FIG. 3F.

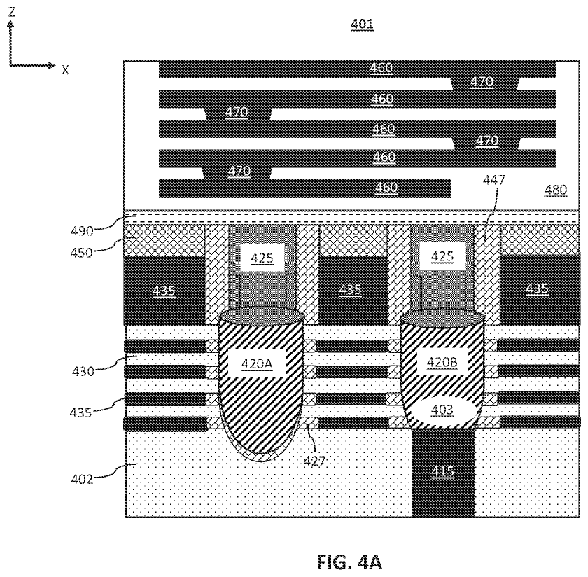

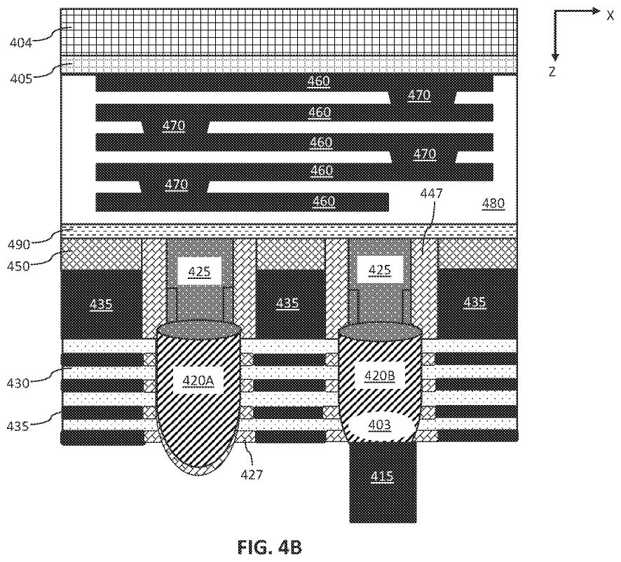

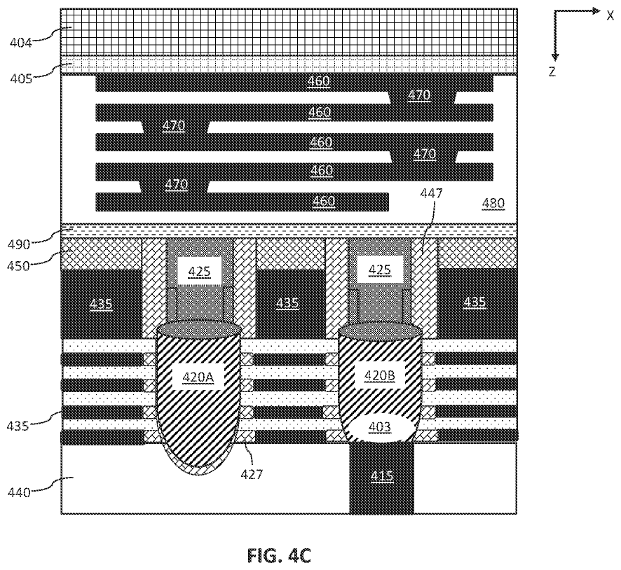

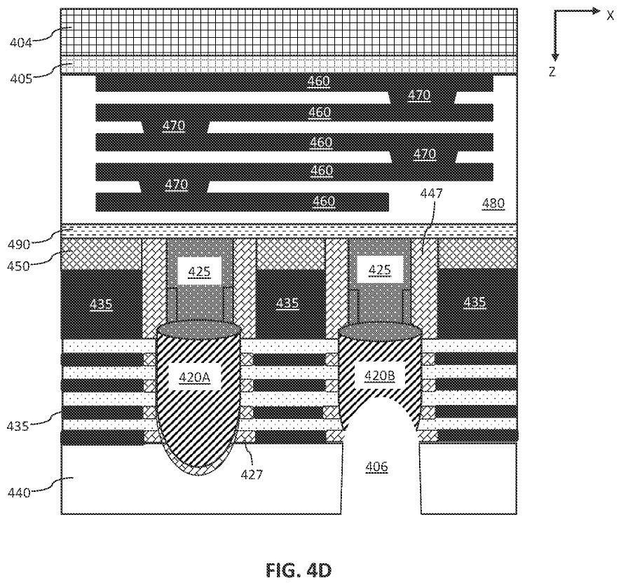

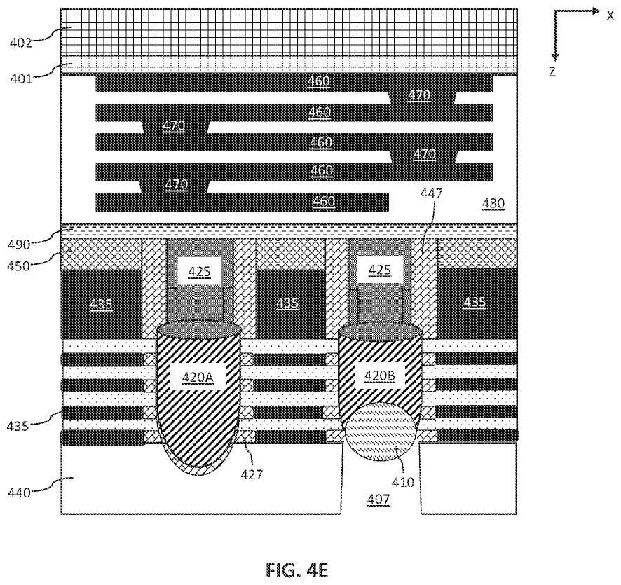

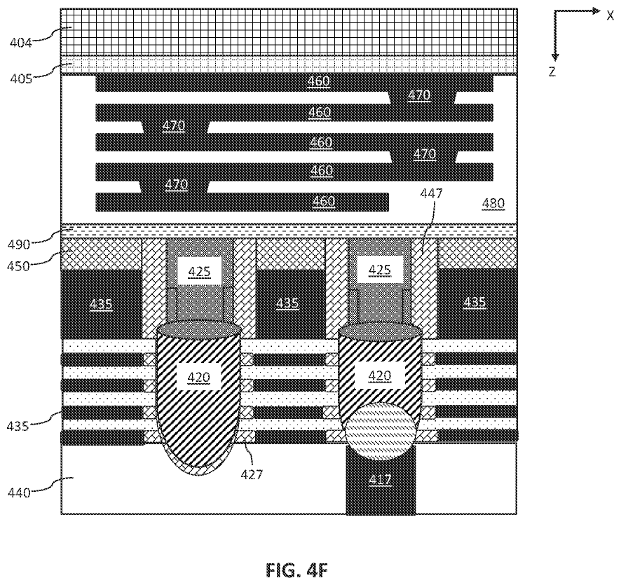

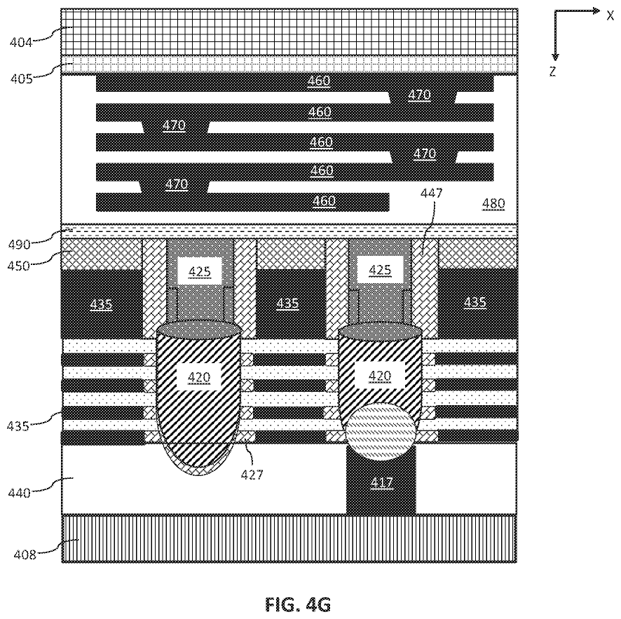

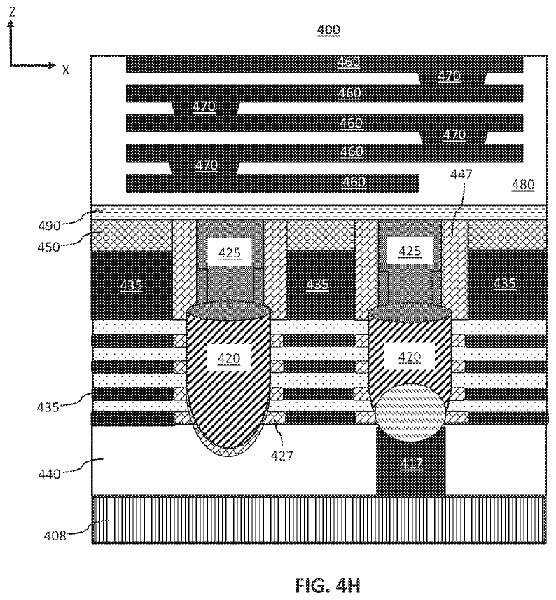

FIGS. 4A-4H illustrate a process of forming an IC device 400 with a backside semiconductor structure 410, according to some embodiments of the disclosure. The IC device 400 may be an example of the IC device 200 in FIG. 2. Although the process is described with reference to the flowchart illustrated in FIGS. 4A-4H, many other processes for forming IC devices with backside semiconductor structures may alternatively be used. For example, the order of the steps described in conjunction with FIGS. 4A-4H may be changed. As another example, some of the steps may be changed, eliminated, or combined.

FIG. 4A shows a preliminary IC device 401 that includes a semiconductor region 402, a backside via 415, semiconductor structures 420A and 420B (collectively referred to as “semiconductor structures 420” or “semiconductor structure 420”), electrodes 425 (individually referred to as “electrode 425”), spacers 427 (individually referred to as “spacer 427”), semiconductor structures 430 (individually referred to as “semiconductor structure 430”), electrodes 435 (individually referred to as “electrode 435”), a gate insulating layer 450, metal layers 460, vias 470, another electrical insulator 480, and a contact layer 490. In other embodiments, the IC device 400 may include fewer, more, or different components. The preliminary IC device 401 may have been formed before the steps illustrated in FIGS. 4B-4H are performed.

The semiconductor structures 420 may include semiconductor materials with dopants, such as the ones described above. As shown in FIG. 4A, the semiconductor structure 420B has a defect 403, which may be a void. The defect 403 can impair the performance of the preliminary IC device 401. The electrodes 425 may be examples of the electrodes 225. The semiconductor structures 430 may be examples of the semiconductor structures 230. The electrodes 435 may be examples of the electrodes 235. The gate insulating layer 450 may be an example of the gate insulating layer 250. The metal layers 460 may be examples of the metal layers 260. The vias 470 may be examples of the vias 270. The electrical insulator 480 may be an example of the electrical insulator 280. The contact layer 490 may be an example of the contact layer 290.

In FIG. 4B, the preliminary IC device 401 is flipped upside down, as illustrated by the Z axis in FIG. 4B. A carrier substrate 404 is attached to the preliminary IC device 401 using a bonding layer 405. The bonding layer may include one or more bonding materials that can affix the carrier substrate 404 onto the preliminary IC device 401. The carrier substrate 404 may facilitate the rest of the process for forming the IC device 100. In some embodiments, after the carrier substrate 404 is attached, the semiconductor region 402 is removed, e.g., through etch, polish, other processes, or some combination thereof. In some embodiments, the entire semiconductor region 402 is removed. In other embodiments, part of the semiconductor region 402 is removed.

In FIG. 4C, an electrical insulator 440 is added. The electrical insulator 440 may include one or more dielectric materials, such as the ones described above. In some embodiments, the electrical insulator 440 may include an oxide. The electrical insulator 440 wraps around the backside via 415. The backside via 415 may penetrate through the electrical insulator 440.

In FIG. 4D, the backside via 415 is removed, e.g., using etch or polish, to expose the defect 403. In some embodiments, a portion of the semiconductor structure 420B may also be removed. An opening region 406 is formed. A portion of the opening region 406 is surrounded by the rest of the semiconductor structure 420B. Another portion of the opening region 406 is surrounded by the electrical insulator 440.

In FIG. 4E, the backside semiconductor structure 410 is formed in the opening region 406. The backside semiconductor structure 410 fills a portion of the opening region 406. The opening region 406 is changed to a new opening region 407. In some embodiments, the backside semiconductor structure 410 may be formed through a low-temperature epitaxial growth process at the backside. For instance, one or more semiconductor materials may be deposited at a relatively low temperature. The backside semiconductor structure 410 is formed through epitaxial growth of the semiconductor materials. One or more precursors may be used for facilitating the epitaxial growth. In some embodiments, the temperature of the epitaxial growth may be below approximately 400° C. Such a temperature is lower compared with the temperature for forming the semiconductor structures 420. For instance, the semiconductor structures 420 may be formed at a temperature above approximately 500° C., e.g., temperatures in a range from approximately 500° C. to approximately 600° C. The lower-temperature epitaxial growth can avoid damage to the other components in the preliminary IC device 401.

The lower-temperature epitaxial growth may use different precursors from the high-temperature epitaxial growth used to grow the semiconductor structures 420. Examples of precursors for the lower-temperature epitaxial growth may include high order precursors, such as Si₂H₆ and Ge₂H₆. Examples of precursors for the lower-temperature epitaxial growth may include SiH4, GeH4, Dichlorosilane (DSC, H₂SiCl₂), hydrochloric acid (HCl), and so on. Given the usage of different precursors in the epitaxial growth processes, the backside semiconductor structure 410 may have one or more different chemical compounds from the semiconductor structures 420. In some embodiments, the backside semiconductor structures 410 may be formed after a surface treatment process that treats the surfaces on which the backside semiconductor structures 410 are to be formed. The surface treatment process may include physical treatment or chemical treatment. The surface treatment process may clean the surfaces, change one or more chemical compounds at the surfaces, or change the surface in other manners to get the surface ready for epitaxial growth.

In FIG. 4F, a new backside via 417 is formed in the opening region 407. The backside via 417 may be formed by depositing one or more metals into the opening region 407. The backside via 417 may extend from the backside surface of the backside semiconductor structure 410 to backside surface of the electrical insulator 440.

In FIG. 4G, a backside metal layer 408 is formed over the electrical insulator 440. The backside metal layer 408 may be connected to the backside via 417. In some embodiments, the backside metal layer 408 and the backside via 417 may be in a power delivery network for delivering power to the backside semiconductor structure 410.

In FIG. 4H, the carrier substrate 304 and the bonding layer 305 are removed. The IC device 300 is formed and flipped back, as indicated by the Z axis in FIG. 4H.

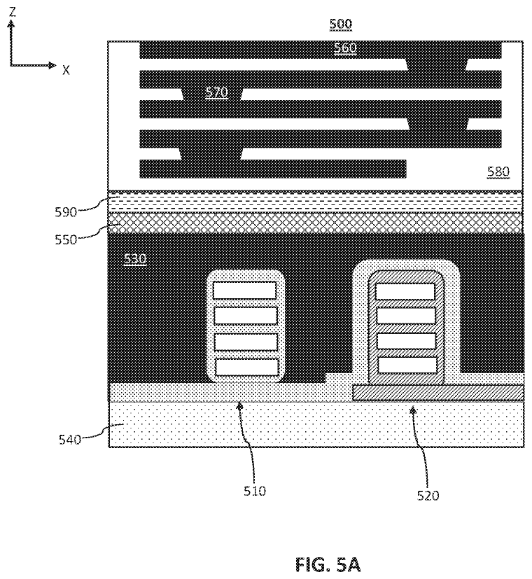

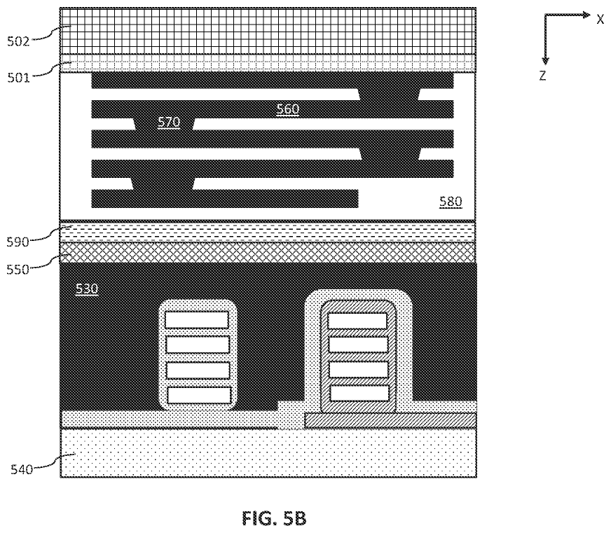

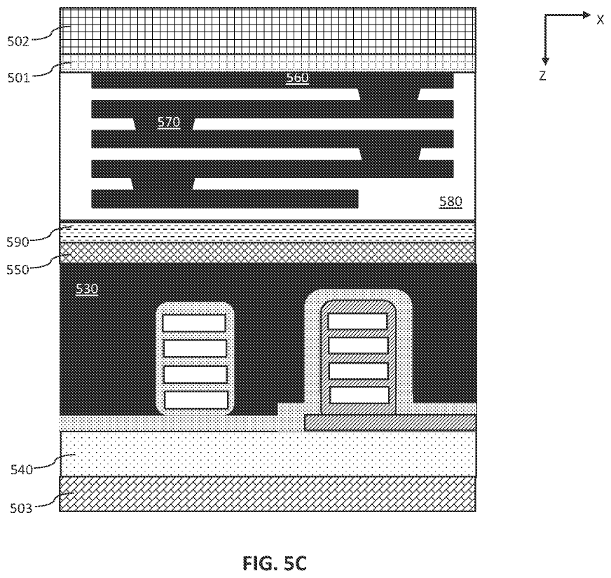

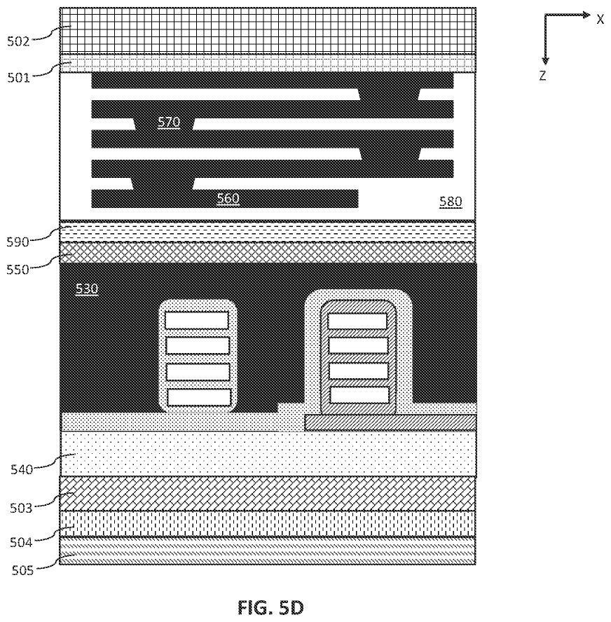

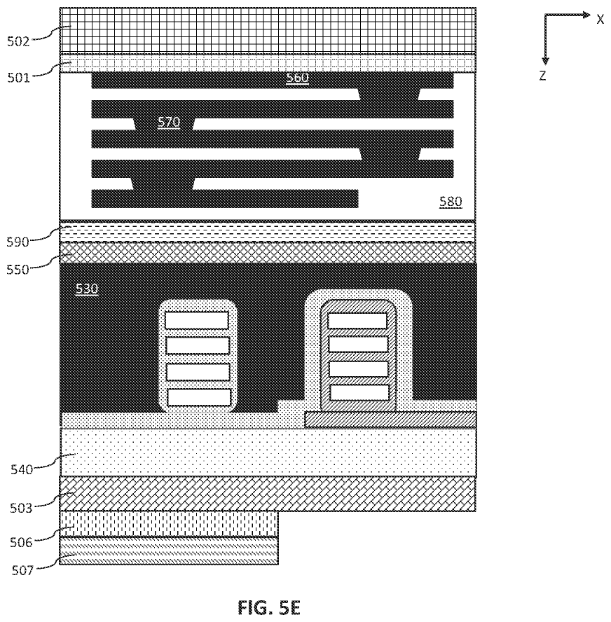

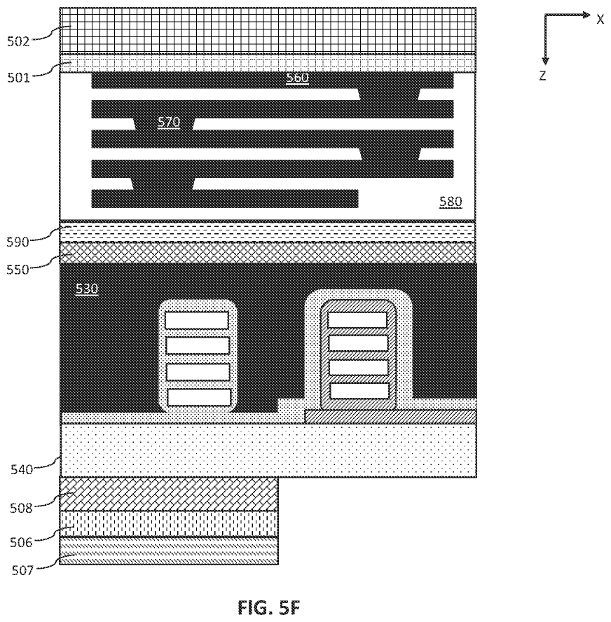

FIGS. 5A-5F illustrate a process of forming backside semiconductor structures in an IC device 500, according to some embodiments of the disclosure. Part of the IC device 500 may be the IC device 100 in FIG. 1 or the IC device 200 in FIG. 2. The IC device 500 may be fabricated through a CMOS process. As shown in FIG. 5A, the IC device 500 includes an N-type transistor 510 and a P-type transistor 520. The N-type transistor 510 may be an NMOS that includes an N-type source region, a N-type drain region and a P-type channel region. The P-type transistor 520 that includes a P-type source region, a P-type drain region and a N-type channel region.

The IC device 500 also includes a conductive structure 530, a support structure 540, a gate insulating layer 350, metal layers 560, vias 570, another electrical insulator 580, and a contact layer 590. In other embodiments, the IC device 500 may include fewer, more, or different components. The conductive structure 530 may be used as gate electrodes of the N-type transistor 510 and a P-type transistor 520. The support structure 540 may be an example of the support structure 105 or 205. The gate insulating layer 550 may be an example of the gate insulating layer 150 or 250. The metal layers 560 may be examples of the metal layers 160 or 260. The vias 570 may be examples of the vias 170 or 270. The electrical insulator 580 may be an example of the electrical insulator 180 or 280. The contact layer 590 may be an example of the contact layer 190 or 290. The CMOS IC device 50 may have been formed before the steps illustrated in FIGS. 5B-5F are performed.

In FIG. 5B, the IC device 500 is flipped upside down, as illustrated by the Z axis in FIG. 4B. A carrier substrate 502 is attached to the IC device 500 using a bonding layer 501. The bonding layer may include one or more bonding materials that can affix the carrier substrate 502 onto the IC device 500. The carrier substrate 502 may facilitate the rest of the process in FIGS. 5C-5F.

In FIG. 5C, a dielectric layer 503 is formed over the support structure 540. The dielectric layer 503 may include a dielectric material, such as a nitride. An example of the dielectric material is silicon nitride. The dielectric layer 503 may be formed by depositing the dielectric material onto the support structure 540.

In FIG. 5D, a polymer layer 504 and a photoresist layer 505 are formed over the dielectric layer 503. The polymer layer 504 is between the dielectric layer 503 and the photoresist layer 505. The polymer layer 504 may be formed by depositing a polymer material onto the dielectric layer 503. Examples of the polymer may include polyethylene, polystyrene, polyvinylchloride, polytetrafluorethylene, polydimethylsiloxane, some polyesters, some polyurethanes, acrylics, epoxies, P(t-Buytl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. The photoresist layer 505 may be formed by depositing a photoresist material onto the polymer layer or spin coating the surface of the polymer layer 504 with a photoresist material.

In FIG. 5E, a portion of the polymer layer 504 and a portion of the photoresist layer 505 are removed (e.g., through lithography or etch processes) to form a new polymer layer 506 and a new photoresist layer 507. In some embodiments, the photoresist layer 505 may be exposed to patterned actinic radiation through a patterned mask, and then the exposed layer may be developed to form the photoresist layer 507. The photoresist layer 507 may be used as an etch mask to etch off the portion of the polymer layer 504 to form the polymer layer 506. Edges of the polymer layer 506 may be aligned with edges the photoresist layer 507 along the X axis.

In FIG. 5F, a portion of the dielectric layer 503 is removed to form a new dielectric layer 508. Edges of the dielectric layer 508 may be aligned with edges of the polymer layer 506 or edges the photoresist layer 507 along the X axis. As shown in FIG. 5E, the dielectric layer 508, polymer layer 506, and photoresist layer 507 are over the N-type transistor 510 along the Z axis but are not over the P-type transistor 520 along the Z axis. The dielectric layer 508, polymer layer 506, and photoresist layer 507 may function as a mask that blocks the N-type transistor 510 when one or more backside semiconductor structures are formed in the P-type transistor 520. Even though not shown in FIGS. 5A-5F, a mask may also be formed to block the P-type transistor 520 when one or more backside semiconductor structures are formed in the N-type transistor 510.

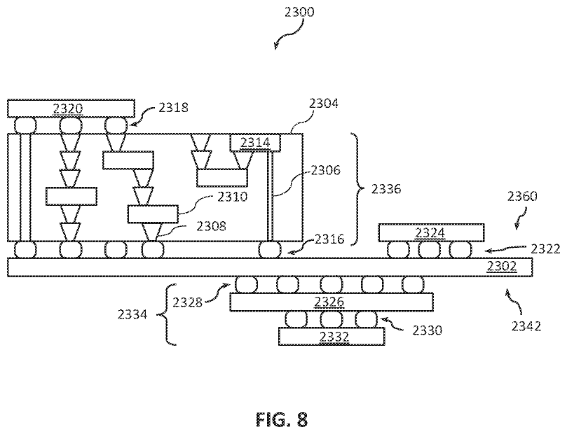

FIGS. 6A and 6B are top views of a wafer 2000 and dies 2002 that may include one or more IC devices with backside semiconductor structures, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. An IC device may include one or more backside semiconductor structures. Examples of the IC device may include the IC device 100, 200, 300, or 400 or the IC device 500. Each of the dies 2002 may be a repeating unit of a semiconductor product that includes any suitable IC (e.g., ICs with backside semiconductor structures as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include backside semiconductor structures as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with backside semiconductor structures, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may include any of the embodiments of an IC device with backside semiconductor structures. In embodiments in which the IC package 2200 includes multiple dies 2256, the IC package 2200 may be referred to as a multi-chip package. Importantly, even in such embodiments of an MCP implementation of the IC package 2200, one or more IC devices with backside semiconductor structures may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, any of the dies 2256 may include one or more backside semiconductor structures as discussed above; in some embodiments, at least some of the dies 2256 may not include any III-N diodes with n-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with backside semiconductor structures, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with backside semiconductor structures in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include backside semiconductor structures in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device 100 of FIG. 1), or any other suitable component. In particular, the IC package 2320 may include one or more IC devices with backside semiconductor structures as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices with backside semiconductor structures as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

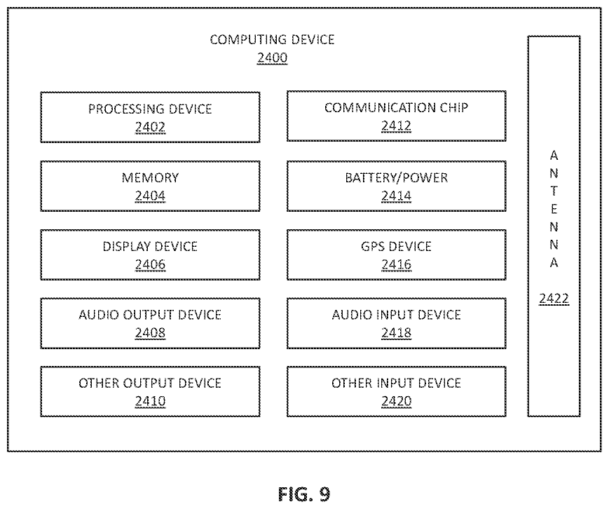

FIG. 9 is a block diagram of an example computing device 2400 that may include one or more components including one or more IC devices with backside semiconductor structures, according to some embodiments of the disclosure. For example, any suitable ones of the components of the computing device 2400 may include a die (e.g., the die 2002 of FIG. 6B) including backside semiconductor structures, according to some embodiments of the disclosure. Any of the components of the computing device 2400 may include an IC device (e.g., the IC devices in FIGS. 1A and 1B) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a source region includes a first semiconductor structure and a second semiconductor structure over the first semiconductor structure; a drain region includes a third semiconductor structure and a fourth semiconductor structure over the third semiconductor structure; a channel region between the source region and the drain region; and an electrical insulator over the source region, drain region, and channel region, in which the second semiconductor structure is between the first semiconductor structure and the electrical insulator, and the fourth semiconductor structure is between the third semiconductor structure and the electrical insulator.

Example 2 provides the IC device according to example 1, in which the first semiconductor structure or the third semiconductor structure includes a first semiconductor material, the second semiconductor structure or the fourth semiconductor structure includes a second semiconductor material, and the first semiconductor material is different from the second semiconductor material.

Example 3 provides the IC device according to example 2, in which a crystal direction of the first semiconductor material is different from a crystal direction of the second semiconductor material.

Example 4 provides the IC device according to example 2 or 3, in which the first semiconductor material has one or more different chemical compounds from the second semiconductor material.

Example 5 provides the IC device according to any one of examples 1-4, further including a conductive layer over the source region, drain region, and channel region, in which the source region, drain region, and channel region are between the conductive layer and the electrical insulator.

Example 6 provides the IC device according to example 5, further including an electrode over the source region, drain region, or channel region, the electrode coupled to the conductive layer.

Example 7 provides the IC device according to any one of examples 1-6, in which the electrical insulator includes an oxide.

Example 8 provides an IC device, including a first semiconductor region includes a first semiconductor structure; a second semiconductor region includes a second semiconductor structure and a third semiconductor structure over the second semiconductor structure; an electrical insulator over the first semiconductor region and the second semiconductor region; and a conductive structure over the third semiconductor structure, the conductive structure at least partially surrounded by the electrical insulator, in which the third semiconductor structure is between the second semiconductor structure and the conductive structure.

Example 9 provides the IC device according to example 8, further including a first conductive layer at a first side of a channel region between the first semiconductor region and the second semiconductor region; and a second conductive layer at a second side of the channel region, in which the second side opposes the first side, the conductive structure is coupled to the second conductive layer, and the electrical insulator is between the channel region and the second conductive layer.

Example 10 provides the IC device according to example 8 or 9, in which a portion of the first semiconductor structure is surrounded by the electrical insulator.

Example 11 provides the IC device according to any one of examples 8-10, in which the first semiconductor region is a P-type semiconductor region, and the second semiconductor region is a N-type semiconductor region.

Example 12 provides the IC device according to any one of examples 8-11, in which: the first semiconductor structure or the second semiconductor structure includes a first semiconductor material, the third semiconductor structure includes a second semiconductor material, and the first semiconductor material is different from the second semiconductor material.

Example 13 provides the IC device according to example 12, in which a crystal direction of the first semiconductor material is different from a crystal direction of the second semiconductor material.

Example 14 provides the IC device according to example 12 or 13, in which the first semiconductor material has one or more different chemical compounds from the second semiconductor material.

Example 15 provides a method of forming an IC device, the method including removing at least part of a semiconductor substrate from a preliminary IC device, in which a first semiconductor structure is over the semiconductor substrate; performing a treatment on a surface of the first semiconductor structure; forming a second semiconductor structure over the first semiconductor structure to form a semiconductor region of a transistor, in which a semiconductor material in the second semiconductor structure is different from a semiconductor material in the first semiconductor structure, and the semiconductor region of the transistor includes the first semiconductor structure and the second semiconductor structure; and forming an electrical insulator over the second semiconductor structure.

Example 16 provides the method according to example 15, further including before removing at least part of the semiconductor substrate, bonding a carrier substrate onto the preliminary IC device, in which the carrier substrate is at a first side of the first semiconductor structure, the semiconductor substrate is at a second side of the first semiconductor structure, and the second side opposes the first side.

Example 17 provides the method according to example 15 or 16, in which the preliminary IC device includes one or more metal layers at a first side of the first semiconductor structure, the semiconductor substrate is at a second side of the first semiconductor structure, and the second side opposes the first side.

Example 18 provides the method according to any one of examples 15-17, in which the first semiconductor structure is formed at a first temperature, the second semiconductor structure is formed at a second temperature, and the second temperature is lower than the first temperature.

Example 19 provides the method according to example 18, in which the second temperature is lower than the first temperature by at least 100° C.

Example 20 provides the method according to any one of examples 15-19, further including after forming the electrical insulator, forming an opening region in the electrical insulator; providing a conductive material into the opening region to form a conductive structure; and after forming the conductive structure, providing a conductive layer over the electrical insulator, in which the conductive structure is between the second semiconductor structure and the conductive layer.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a source region comprises a first semiconductor structure and a second semiconductor structure over the first semiconductor structure;
a drain region comprises a third semiconductor structure and a fourth semiconductor structure over the third semiconductor structure;
a channel region between the source region and the drain region; and
an electrical insulator over the source region, drain region, and channel region,
wherein the second semiconductor structure is between the first semiconductor structure and the electrical insulator, and the fourth semiconductor structure is between the third semiconductor structure and the electrical insulator.

2. The IC device according to claim 1, wherein:
the first semiconductor structure or the third semiconductor structure comprises a first semiconductor material,
the second semiconductor structure or the fourth semiconductor structure comprises a second semiconductor material, and
the first semiconductor material is different from the second semiconductor material.

3. The IC device according to claim 2, wherein a crystal direction of the first semiconductor material is different from a crystal direction of the second semiconductor material.

4. The IC device according to claim 2, wherein the first semiconductor material has one or more different chemical compounds from the second semiconductor material.

5. The IC device according to claim 1, further comprising:
a conductive layer over the source region, drain region, and channel region,
wherein the source region, drain region, and channel region are between the conductive layer and the electrical insulator.

6. The IC device according to claim 5, further comprising:
an electrode over the source region, drain region, or channel region, the electrode coupled to the conductive layer.

7. The IC device according to claim 1, wherein the electrical insulator comprises an oxide.

8. An integrated circuit (IC) device, comprising:
a first semiconductor region comprises a first semiconductor structure;
a second semiconductor region comprises a second semiconductor structure and a third semiconductor structure over the second semiconductor structure;
an electrical insulator over the first semiconductor region and the second semiconductor region; and
a conductive structure over the third semiconductor structure, the conductive structure at least partially surrounded by the electrical insulator,
wherein the third semiconductor structure is between the second semiconductor structure and the conductive structure.

9. The IC device according to claim 8, further comprising:
a first conductive layer at a first side of a channel region between the first semiconductor region and the second semiconductor region; and
a second conductive layer at a second side of the channel region,
wherein the second side opposes the first side, the conductive structure is coupled to the second conductive layer, and the electrical insulator is between the channel region and the second conductive layer.

10. The IC device according to claim 8, wherein a portion of the first semiconductor structure is surrounded by the electrical insulator.

11. The IC device according to claim 8, wherein the first semiconductor region is a P-type semiconductor region, and the second semiconductor region is a N-type semiconductor region.

12. The IC device according to claim 8, wherein:
the first semiconductor structure or the second semiconductor structure comprises a first semiconductor material,
the third semiconductor structure comprises a second semiconductor material, and
the first semiconductor material is different from the second semiconductor material.

13. The IC device according to claim 12, wherein a crystal direction of the first semiconductor material is different from a crystal direction of the second semiconductor material.

14. The IC device according to claim 12, wherein the first semiconductor material has one or more different chemical compounds from the second semiconductor material.

15. A method of forming an integrated circuit (IC) device, the method comprising:
removing at least part of a semiconductor substrate from a preliminary IC device, wherein a first semiconductor structure is over the semiconductor substrate;
performing a treatment on a surface of the first semiconductor structure;
forming a second semiconductor structure over the first semiconductor structure to form a semiconductor region of a transistor, wherein a semiconductor material in the second semiconductor structure is different from a semiconductor material in the first semiconductor structure, and the semiconductor region of the transistor comprises the first semiconductor structure and the second semiconductor structure; and
forming an electrical insulator over the second semiconductor structure.

16. The method according to claim 15, further comprising:
before removing at least part of the semiconductor substrate, bonding a carrier substrate onto the preliminary IC device,
wherein the carrier substrate is at a first side of the first semiconductor structure, the semiconductor substrate is at a second side of the first semiconductor structure, and the second side opposes the first side.

17. The method according to claim 15, wherein the preliminary IC device comprises one or more metal layers at a first side of the first semiconductor structure, the semiconductor substrate is at a second side of the first semiconductor structure, and the second side opposes the first side.

18. The method according to claim 15, wherein the first semiconductor structure is formed at a first temperature, the second semiconductor structure is formed at a second temperature, and the second temperature is lower than the first temperature.

19. The method according to claim 18, wherein the second temperature is lower than the first temperature by at least 100° C.

20. The method according to claim 15, further comprising:
after forming the electrical insulator, forming an opening region in the electrical insulator;
providing a conductive material into the opening region to form a conductive structure; and
after forming the conductive structure, providing a conductive layer over the electrical insulator,
wherein the conductive structure is between the second semiconductor structure and the conductive layer.
